(19) United States
(12) Patent Application Publication
(10) Pub. No.: US 2013/0234287 A1
(43) Pub. Date: Sep. 12, 2013

(54) HIGH PRECISION CAPACITOR WITH LOW VOLTAGE COEFFICIENT OF CAPACITANCE AND METHOD FOR MANUFACTURING THE SAME

(71) Applicants: Badih EL-KAREH, Seoul (KR); JONG HO LEE, Seoul (KR); DONGSEOK KIM, Seoul (KR); CHANG EUN LEE, Seoul (KR); Jung-Joo KIM, Seoul (KR)

(72) Inventors: Badih EL-KAREH, Seoul (KR); JONG HO LEE, Seoul (KR); DONGSEOK KIM, Seoul (KR); CHANG EUN LEE, Seoul (KR); Jung-Joo KIM, Seoul (KR)

(73) Assignee: Dongbu HiTek Co., Ltd., Seoul (KR)

(21) Appl. No.: 13/463,334

(22) Filed: May 3, 2012

(30) Foreign Application Priority Data
Mar. 12, 2012 (KR) 10-2012-0025089

(51) Int. Cl. H01L 29/86; H01L 21/02

(52) U.S. Cl. 257/532; 438/396; 257/E29.343; 257/E21.011

(57) ABSTRACT

A high-precision capacitor includes a first degenerately doped polysilicon plate, a second degenerately doped polysilicon plate, and a dielectric material disposed between the first and the second degenerately doped polysilicon plates. The first degenerately doped polysilicon plate may be formed by performing POCL (phosphorus oxychloride) diffusion, and performing ion implantation through the POCL oxide to replenish the loss of dopants. The second degenerately doped polysilicon plate may be formed by performing POCL doping. The high-precision capacitor may exhibit a voltage coefficient of capacitance (VCC) comparable to a Metal-Insulator-Metal capacitor, however, with a dielectric of higher quality.

The present invention claims priority under 35 U.S.C. §119 to Korean Patent Application No. 10-2012-0025089 (filed on Mar. 12, 2012), which is hereby incorporated by reference in its entirety.

### BACKGROUND

Capacitors may be employed in digital and analog devices for a variety of purposes, including sample and hold circuits, data converters, filters, and circuits for storing electrical charge, blocking DC voltage levels, and stabilizing power supplies. In particular, CMOS IC logic devices require high precision analog capacitors. Several types of high precision capacitors have been integrated in analog CMOS technologies with varying degrees of complexity. The high precision capacitors may include a metal-insulator-metal (MIM) planar capacitor, a metal-to-metal fractal capacitor, a metal-insulator-silicide (MIS) capacitor, and a polysilicon-insulator-polysilicon (PIP) capacitor, among other types.

One important parameter for the design of high precision capacitors is the Voltage Coefficient of Capacitance (VCC). This refers to the change in capacitance as the voltage across two electrode plates of the capacitor changes. It is desirable to provide the high precision capacitors having small VCC values.

Another important parameter is dielectric absorption (DA) in capacitors. The dielectric absorption is related to traps in the dielectric material. The traps can be charged when a voltage is applied to the electrode plates and then slowly discharge to the surface after the voltage is removed.

Ideally, the voltage across the electrode plates should be zero when an external voltage is removed. In the presence of traps, however, the voltage across the electrode plates rises slowly, even after the external voltage is removed, because of discharging traps. This is similar to a material that absorbs water and the water slowly seeps to the surface, wetting the surface even after it has been initially dried. A very low dielectric absorption is desired for precision analog circuits.

For RF applications, a capacitor should have a high quality factor (Q-factor), i.e., minimal losses to other components and layers, particularly to a substrate of a semiconductor device. The capacitor should also have an optimized, not too high and not too low, capacitance per unit area, and exhibit low leakage through the dielectric material when the maximum voltage is applied across the electrode plates.

The above properties of the capacitor cannot always be simultaneously satisfied. For example, the MIM capacitor has electrode plates made of metal that may have an extremely high concentration of electrons, and therefore, VCC of the MIM capacitor is extremely low. Also, since the electrode plates are placed high above a substrate of a semiconductor device, the Q-factor is high. In addition, the MIM capacitor has a very low parasitic capacitance. The MIM capacitor is problematic in that a dielectric quality, such as DA or leakage, is on the poor side because the temperature in which a dielectric material can be deposited or annealed is limited. For example, in the case of aluminum plates, the temperature is limited to about 475° C.

For the PIP capacitor, the electrode plates are manufactured by simply implanting dopants into electrode plates and annealing the electrode plates, resulting in a not sufficiently high polysilicon carrier concentration at interfaces. Therefore, the PIP capacitor has the drawback of high VCC owing to the low polysilicon carrier concentration. The PIP capacitor, however, allows the deposition and anneal of high-quality dielectrics with very low dielectric absorption.

One well-known method to increase the polysilicon carrier concentration is to dope the electrode plates by phosphorus oxychloride POCl₃, or simply “POCL”. Phosphorus doping by POCL injection alone has, however, its own limitations when integrating the PIP capacitor in a CMOS-base technology. One of the limitations is the loss of dopants during oxidation and etching.

FIGS. 1A and 1B illustrate a process of manufacturing a high precision PIP capacitor in accordance with the related art.

Referring to FIG. 1A, first, a substrate 10, such as a silicon wafer, is provided on which a capacitor part 110 and a transistor part 120 are defined in specific areas. A field oxide is pattered on the substrate 10 and filled with oxide to form shallow trench isolation (STI) regions 12. The STI regions 12 isolate components from each other, in particular, the capacitor part 110 from the transistor part 120.

Next, a gate oxide 13, a polysilicon layer 14, which will be used to form a lower electrode plate of a PIP capacitor and gate electrodes of the transistor, and a hard-mask 16, typically 50-nm oxide, may be deposited sequentially. Thereafter, a photo-resist (not shown) may be formed on the hard-mask 16 and is selectively patterned to define an exposed region in the polysilicon layer 14. Subsequently, the exposed region in the polysilicon layer 14 is subjected to a phosphorus oxychloride POCl₃ (POCL) atmosphere.

In this process, phosphorus is evaporated from a liquid source of phosphorus oxychloride into the exposed region in the polysilicon layer 14. A bubbler converts the liquid source to vapor using oxygen as a carrier gas that flows through the liquid source. The liquid source may be kept at a constant temperature. The vapor is transported from the bubbler to the diffusion furnace by the carrier gas. At the diffusion temperature, the phosphorus oxychloride POCl₃ reacts with the carrier gas to form phosphorus pentoxide 18 on the surface of the exposed region. The reaction can be expressed as follows:

4POCl₃+3O₂→2P₂O₅+6Cl₂

The phosphorus pentoxide 18 is incorporated into the oxide grown on the polysilicon layer 14 since the carrier gas is oxygen. The doped oxide is the source of diffusion into the polysilicon layer 14.

As shown in FIG. 1B, after the POCL diffusion, the doped oxide may be removed in preparation for subsequent processes, e.g., the deposition of an inter-poly dielectric and formation of an upper electrode plate (not shown). In some applications, the doped oxide may be left to act as an inter-poly dielectric. For precision capacitors, however, the doped oxide may be removed and replaced by a higher-quality inter-poly dielectric.

During this process, an appreciable fraction of dopants is removed with the doped oxide, which is followed by a loss of dopants during subsequent thermal cycles. The net result is a reduction in phosphorus concentration at the interface of the polysilicon layer 14 with the inter-poly dielectric, which results in higher VCC. It is this concentration at the interface that primarily determine the VCC.

Therefore, there is a need for precision PIP capacitor, with low VCC that approximates a MIM capacitor and a method of fabricating the same.

### SUMMARY

Embodiments relate to semiconductor devices and more particularly, to a high-precision capacitor with low Voltage Coefficient of Capacitance (VCC) in a CMOS-base technology and a method for manufacturing the same.

Embodiments relate to a precision PIP capacitor, with low VCC and a method of manufacturing the same, capable of replenishing the loss of dopants during thermal cycles.

In accordance with embodiments, there is provided a high-precision capacitor, which includes a first degenerately doped polysilicon plate, a second degenerately doped polysilicon plate, and a dielectric material deposited between the first and the second degenerately doped polysilicon plates.

The first degenerately doped polysilicon plate may be formed by performing POCL (phosphorus oxychloride) diffusion, during which an oxide film, referred to as POCL oxide, is formed, and implanting phosphorus and/or arsenic through the POCL oxide to replenish the loss of dopants.

The doped oxide may be removed, followed by depositing an inter-poly dielectric such as but not limited to silicon-dioxide. It can also be left as an inter-poly dielectric.

A second degenerately doped polysilicon plate may then be deposited and also doped by POCL injection.

In accordance with embodiments, there is provided a method for manufacturing a high-precision capacitor, which includes forming a first degenerately doped polysilicon plate, depositing a dielectric layer on the first degenerately doped polysilicon plate, and forming a second degenerately doped polysilicon plate.

The forming the first degenerately doped polysilicon plate may include defining a first polysilicon region on a STI (shallow trench isolation) layer in a semiconductor substrate, performing a POCL diffusion on the doped first polysilicon region to produce the degenerately doped first polysilicon plate, and implanting arsenic and/or phosphorus through the POCL-grown oxide at an appropriate energy and dose to replenish the loss of dopants.

The forming the second degenerately doped polysilicon plate may include performing a POCL doping on the doped second polysilicon region to produce the degenerately doped second polysilicon plate.

### DRAWINGS

The objects and features of embodiments will become apparent from the following description, given in conjunction with the accompanying drawings, in which:

FIGS. 1A and 1B illustrate a schematic process of manufacturing a high precision PIP capacitor in accordance with the related art.

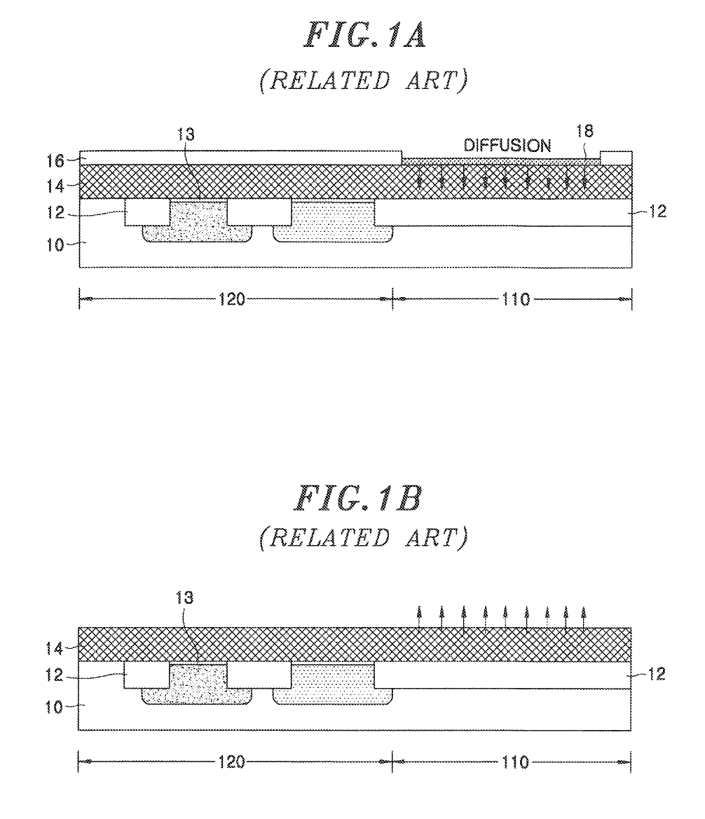

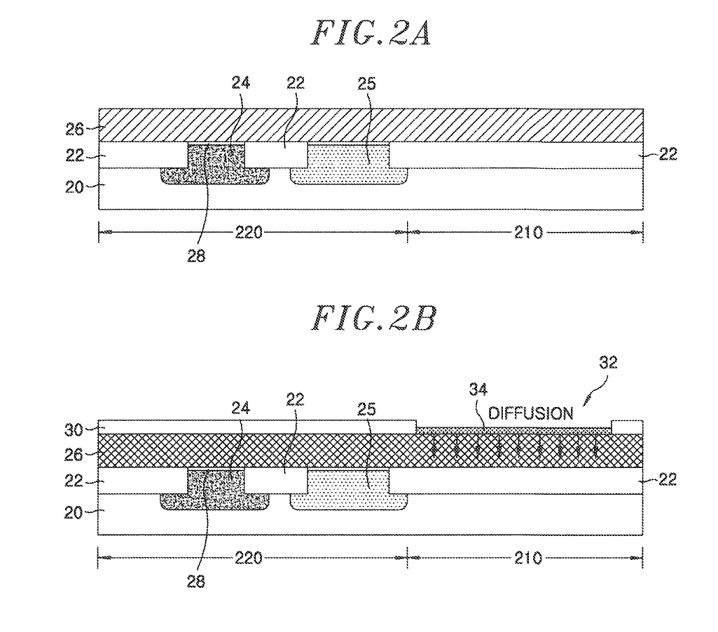

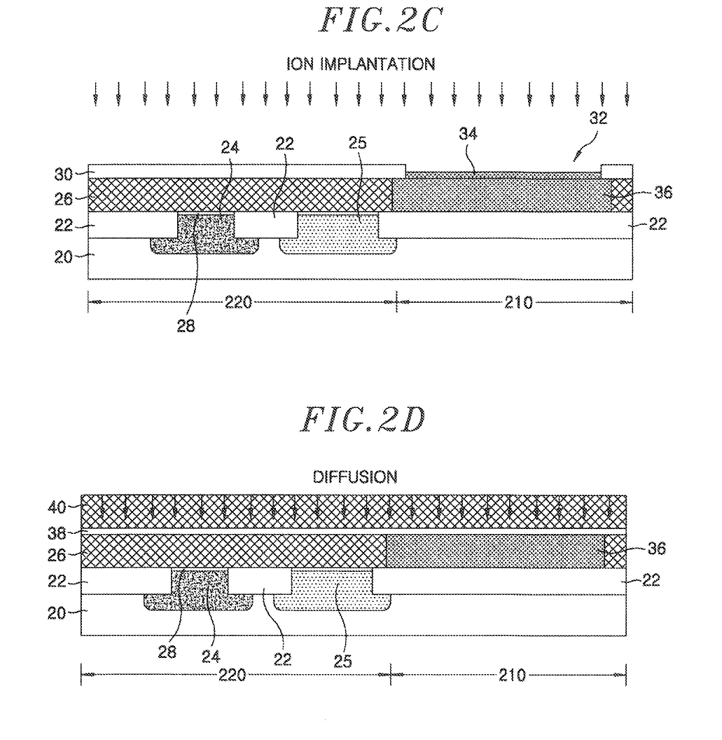

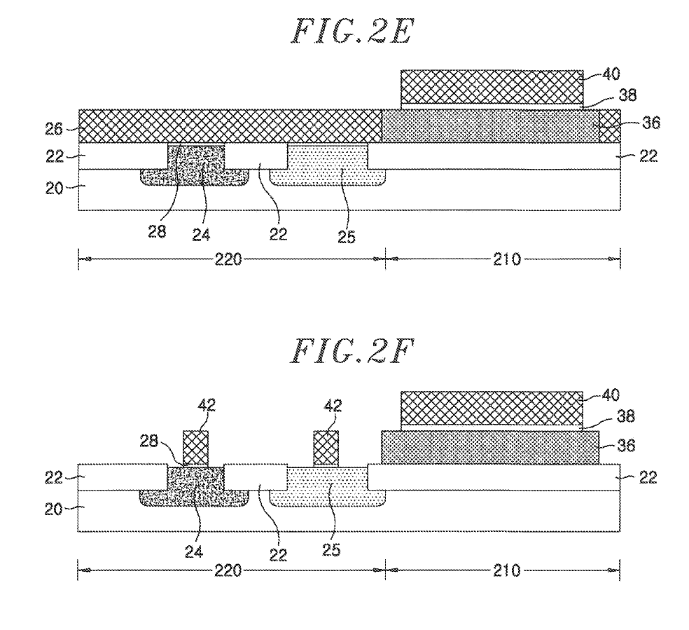

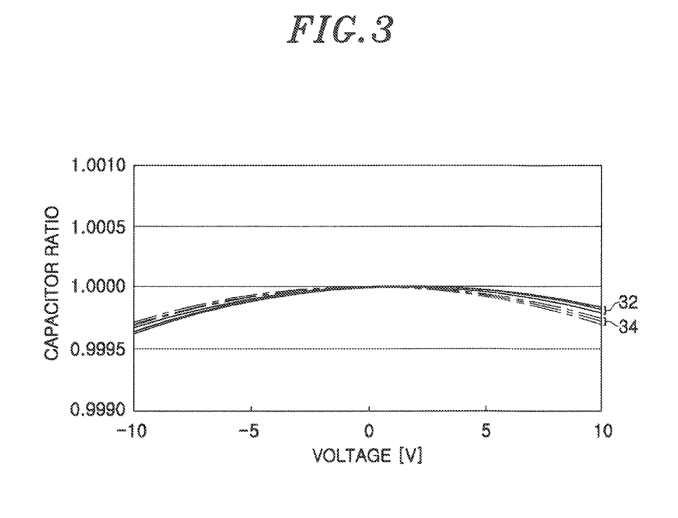

Example FIGS. 2A to 2F illustrate a process of manufacturing a high precision PIP capacitor with very low Voltage Coefficient of Capacitance formed in a CMOS-base technology, in accordance with embodiments.

Example FIG. 3 is a graph illustrating VCCs measured in a PIP capacitor according to embodiments.

### DESCRIPTION

Hereinafter, embodiments will be described with reference to the accompanying drawings which form a part hereof. Wherever possible, the same or like reference numerals will be used throughout the drawings to refer to the same or like components.

Example FIGS. 2A to 2F illustrate a process of manufacturing a high precision PIP capacitor with very low Voltage Coefficient of Capacitance (VCC) in a CMOS device, in accordance with embodiments. The following description is made in relation to a high precision PIP capacitor in accordance with embodiments. Manufacturing steps that are either standard or well-known or disclosed elsewhere will not be described in detail.

Referring to example FIG. 2A, first, a substrate 20, such as a silicon wafer, is provided on and/or over which a capacitor part 210 and a transistor part 220 may be defined in specific areas. A shallow trench isolation (STI) layer 22 may be formed on and/or over the capacitor part 210 and the transistor part 220 on and/or over the substrate 20 to isolate components, in particular, the capacitor part 210 and the transistor part 220, from each other. As illustrated in example FIG. 2A, P-well 24 and N-well 25 may be formed in the transistor part 220.

Next, a gate oxide 28 may be grown, and a first polysilicon layer 26, having a thickness of about 0.4 μm may an be deposited and used to form a lower electrode plate of the PIP capacitor and gate electrode of the transistor. The first polysilicon layer 26 may be deposited almost intrinsic or lightly doped in either polarity.

As illustrated in FIG. 2B, a hard-mask 30, which may be an oxide having a thickness of about 500 Å, may be deposited over the first polysilicon layer 26. The hard mask 30 may then be patterned to define an exposed region 32 of the first polysilicon layer 26. Thereafter, the exposed region 32 may be subjected to a phosphorus oxychloride POCl₃ (or simply POCL) doping at a constant temperature in a diffusion furnace. During POCL doping, the surface of the first polysilicon layer 26 may be oxidized to form a doped oxide film 34 with phosphorus pentoxide P₂O₅. The doped oxide film 34 becomes a diffusion source with high dopant concentration and serves to dope the exposed region 32 of the first polysilicon layer 26. By virtue of the diffusion source, the first polysilicon layer 26 has a highly doped first polysilicon region 36 therein as illustrated in FIG. 2C.

Thereafter, the doped oxide film 34 may be removed and an ion implantation process may then be performed to introduce dopants at a dose of about 1E16 atoms/cm⁻³ into the first polysilicon layer 26. Alternatively, the doped oxide film 34, referred to as a POCL oxide, may be left to act as an inter-poly dielectric.

The ion implantation may compensate for the loss of dopants during the growth of doped oxide film 34 and its subsequent removal. The placement of the implanted peak below POCL oxide film 34 is critical. For a sufficiently thick hard mask 30, this ion implantation step can be done without an additional masking step since the hard mask 30 can stop the implant outside of the exposed region 32. In embodiments, the dopant for the ion implantation may include phosphorus and/or arsenic. The phosphorus and/or arsenic may be implanted independently or a combination of phosphorus and arsenic may be implanted simultaneously.

The combination of POCL doping and phosphorus and/or arsenic implantation ensures that the top surface of the first polysilicon layer 26 may be degenerately doped.

Without the implantation of the phosphorus and/or arsenic, the loss of dopants from the surface of first polysilicon layer 26 during the growth of the doped oxide film 34 and removal of the doped oxide film 34 would cause the VCC to substantially increase. In contrast, the implantation of the phosphorus and/or arsenic replenishes and/or compensates for the loss of dopants from the top surface of the first polysilicon layer 26 that occurs after the doped oxide film 34 is removed, which results in reducing the VCC.

As illustrated in FIG. 2D, after removing the hard mask 30, a suitable dielectric material such as but not limited to silicon-dioxide and of about 25 to 50 nm in thickness, may be deposited onto the doped first polysilicon layer 26 to form an inter-poly dielectric layer 38. Next, an undoped second polysilicon layer 40, of about 250 to 500 nm in thickness may be deposited on the inter-poly dielectric layer 38 in order to form the upper electrode plate of the PIP capacitor. The second polysilicon layer 40 may then be degenerately doped by performing a POCL doping following a similar procedure as for the first polysilicon layer 26, however, without patterning, i.e., blanket doped. The loss of dopant due to the POCL oxidation of the surface of the second polysilicon layer 40 is not of any major concern since this does not affect the interface between the second polysilicon layer 40 and the inter-poly dielectric layer 38.

The combination of POCL injection and implantation steps as described above ensures that the polysilicon 36 and the polysilicon 40 may be degenerately doped at both their interfaces with inter-poly oxide 38, resulting in very low VCC in both voltage polarities.

Thereafter, the highly-doped second polysilicon layer 40 and the inter-poly dielectric layer 38 may be patterned simultaneously, stopping on the first polysilicon layer 26 to keep a portion of the highly-doped second polysilicon layer 40 as an upper electrode plate of the PIP capacitor, as illustrated in FIG. 2E.

The first polysilicon layer 26 may then be selectively implanted over the CMOS regions, using photo-resist masking steps.

Finally, as illustrated in FIG. 2F, the first polysilicon layer 26 and the highly-doped first polysilicon region 36 may be simultaneously patterned using masking resist patterns (not shown), thereby forming the high precision PIP capacitor and the CMOS structures with polysilicon gates 42.

Further CMOS related processing may be performed as desired.

Example FIG. 3 is a graph illustrating VCCs measured in the disclosed PIP capacitor. In example FIG. 3, a set of curves 32 denotes the VCC of the disclosed PIP capacitor with a silicided contacting structure and a set of curves 34 denotes the VCC of the disclosed PIP capacitor with a non-silicided contacting structure.

The following table compares the VCC of a PIP capacitor in accordance with embodiments and a related art MIM capacitor having a same dielectric thickness of 38 nm.

TABLE
VCC comparison of PIP to MIM capacitors

| | PIP capacitor | MIM capacitor |
|---|---|---|
| Linear VCC, VCC-1 | +2 ppm/V | −14 ppm/V |
| Quadratic: VCC, VCC-2 | −3 ppm/V² | −4 ppm/V² |
| Capacitance fF/μm² | ~0.9 | ~1.0 |

The PIP capacitor in accordance with embodiments exhibits a low VCC comparable to that of the MIM capacitor, however, with an expected higher dielectric quality.

While embodiments have been shown and described, it will be understood by those skilled in the art that various changes and modification may be made without departing from the scope of the embodiments as defined in the following claims.

What is claimed is:

1. A high-precision capacitor, comprising:
a first degenerately doped polysilicon plate;
a second degenerately doped polysilicon plate; and
a dielectric material deposited between the first and the second degenerately doped polysilicon plates.

2. The high-precision capacitor of claim 1, wherein the first degenerately doped polysilicon plate is formed by POCL (phosphorus oxychloride) doping during which a POCL oxide film is formed, and ion implantation to replenish a loss of dopants; and
wherein the second degenerately doped polysilicon plate is formed by POCL doping.

3. The high-precision capacitor of claim 2, wherein a dopant for the ion implantation comprises phosphorus and/or arsenic implanted after POCL oxidation.

4. A method for manufacturing a high-precision capacitor, the method comprising:
forming a lower electrode plate made of a degenerately doped polysilicon;
depositing a dielectric material on the lower electrode plate; and
forming an upper electrode plate made of a degenerately doped polysilicon on the dielectric material.

5. The method of claim 4, wherein the forming the lower electrode plate made of the degenerately doped polysilicon comprises:
forming a first polysilicon layer on an STI (shallow trench isolation) layer in a semiconductor substrate;
performing a POCL (phosphorus oxychloride) doping on a portion of the first polysilicon layer to form a POCL oxide film on a surface of the portion of the first polysilicon layer; and
doping the first polysilicon layer by ion implantation, to make the portion of the first polysilicon layer to be degenerately doped as the lower electrode plate.

6. The method of claim 4, wherein the forming the upper electrode plate made of the degenerately doped polysilicon comprises:
forming a second polysilicon layer on the dielectric material;
performing a POCL (phosphorus oxychloride) doping on the second polysilicon layer to make the second polysilicon layer to be degenerately doped; and
patterning the degenerately doped second polysilicon layer and the dielectric material to define a portion of the degenerately doped second polysilicon layer as the upper electrode plate.

7. The method of claim 5, wherein a dopant for the ion implantation comprises phosphorus and/or arsenic.

8. The method of claim 5, wherein the POCL oxide film becomes a diffusion source to dope the portion of the first polysilicon layer.

9. The method of claim 5, wherein the forming the lower electrode plate further comprises:
removing the POCL oxide film before doping the first polysilicon layer by ion implantation,
wherein the ion implantation serves to replenish a loss of dopants caused by the removal of the POCL oxide film.

10. The method of claim 4, wherein the forming the lower electrode plate comprises:
forming a first polysilicon layer on an STI (shallow trench isolation) layer in a semiconductor substrate;
performing a POCL (phosphorus oxychloride) doping on a portion of the first polysilicon layer to form a POCL oxide film on a surface of the portion of the first polysilicon layer; and
doping the first polysilicon layer by ion implantation through the POCL oxide film, to make the portion of the first polysilicon layer to be degenerately doped as the lower electrode plate.

11. The method of claim 10, wherein the forming the lower electrode plate further comprises:
removing the POCL oxide film after doping the first polysilicon layer by ion implantation,
wherein the ion implantation serves to replenish a loss of dopants caused by the removal of the POCL oxide film.
